(19) United States
(12) Patent Application Publication
(10) Pub. No.: US 2024/0387542 A1
(43) Pub. Date: Nov. 21, 2024

(54) SEMICONDUCTOR DEVICE AND SEMICONDUCTOR DIE

(71) Applicant: Taiwan Semiconductor Manufacturing Company, Ltd., Hsinchu (TW)

(72) Inventors: Yun-Feng Kao, New Taipei City (TW); Katherine H. CHIANG, New Taipei City (TW)

(73) Assignee: Taiwan Semiconductor Manufacturing Company, Ltd., Hsinchu (TW)

(21) Appl. No.: 18/320,153

(22) Filed: May 18, 2023

(51) Int. Cl. H01L 27/092; H01L 21/8238

(52) U.S. Cl. CPC H01L 27/0922; H01L 21/823807; H01L 21/823814

(57) ABSTRACT

A semiconductor device includes a first gate, a second gate disposed over the first gate, a first contact, a second contact, a third contact disposed between the first gate and the second gate, a first semiconductor layer, and a second semiconductor layer. The first semiconductor layer is disposed between the first gate and the third contact. The first semiconductor layer includes a first channel region, a first source region, and a first drain region, and the first channel region laterally extends between the first drain region and the first contact. The second semiconductor layer is disposed between the second gate and the third contact. The second semiconductor layer includes a second channel region, a second source region, and a second drain region, and the second channel region laterally extends between the second drain region and the second contact.

### BACKGROUND

Semiconductor devices used to generate logic functions are known as Complementary Metal-Oxide-Semiconductor (CMOS) inverters. The CMOS inverters are essential components fabricated in semiconductor dies. The CMOS inverters are field effect transistors (FETs) including a metal gate that lies on top of insulating oxide layer on top of a semiconductor material. The CMOS inverters are used and fabricated in most electronic devices for generating data. The CMOS inverters reverse an applied input signal. In digital logic circuits, binary arithmetic and switching or logic function's mathematical manipulation are performed through the symbols 0 and 1. When the input logic is low (e.g., 0), the output of the CMOS inverters is high (e.g., 1); and when the input logic is high (e.g., 1), the output of the CMOS inverters is low (e.g., 0).

Currently, the quality of the CMOS inverters can be estimated by measuring the Voltage Transfer Characteristics (VTC) of the CMOS inverters. Due to the difference between materials and mobilities of p-type channel and n-type channel of the CMOS inverters, the VTC shifts and thus the performance of the CMOS inverters deteriorates. Accordingly, improvement on reliability of the CMOS inverters is needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a circuit diagram schematically illustrating an inverter in accordance with some embodiments of the present disclosure.

FIG. 2 is a perspective view schematically illustrating a semiconductor die in accordance with some embodiments of the present disclosure.

FIG. 3 through FIG. 13 are cross-sectional views schematically illustrating a process flow for fabricating an inverter embedded in an interconnect structure of a semiconductor die in accordance with some embodiments of the present disclosure.

FIG. 14A through FIG. 14G schematically illustrate layouts of various thin films in an inverter in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

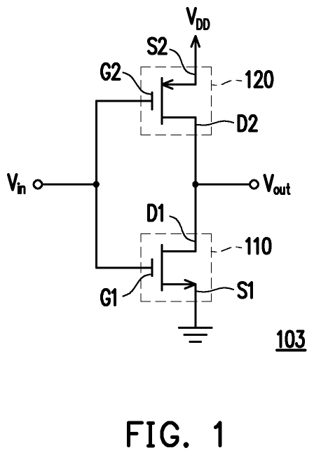

FIG. 1 is a circuit diagram schematically illustrating an inverter in accordance with some embodiments of the present disclosure.

Referring to FIG. 1, an inverter 103 in accordance with some embodiments of the present disclosure includes an n-type field effect transistor (FET) 110 and a p-type FET 120 electrically connected to the n-type FET 110. The first drain DI of the n-type FET 110 is electrically connected to the second drain D2 of the p-type FET 120, and the first gate G1 of the n-type FET 110 is electrically connected to the second gate G2 of the p-type FET 120. As illustrated in FIG. 1, the first drain D1 and the second drain D2 are electrically connected to an output terminal for outputting an output voltage Vₒᵤₜ, the first gate G1 and the second gate G2 are electrically connected to an input terminal for receiving an input voltage Vᵢₙ, and a first source S1 of the n-type FET 110 is electrically connected to a high voltage level V_{DD} (e.g., a supply voltage V_{DD}), and a second source S2 of the p-type FET 120 is electrically connected to a low voltage level GND (e.g., electrically grounded). When a low input voltage Vᵢₙ (e.g., Vᵢₙ=0 volt) is applied to the first gate G1 and the second gate G2 in the inverter 103, the p-type FET 120 is switched “ON” whereas the n-type FET 110 is switched “OFF”, and thus the inverter 103 outputs a high output voltage Vₒᵤₜ (i.e., Vₒᵤₜ=V_{DD}). Similarly, when a high input voltage Vᵢₙ (e.g., Vᵢₙ=5 volts) is applied to the first gate G1 and the second gate G2 in the inverter 103, the p-type FET 120 is switched “OFF whereas the n-type FET 110 is switched “ON”, and thus the inverter 103 outputs a low output voltage Vₒᵤₜ (i.e., Vₒᵤₜ=GND).

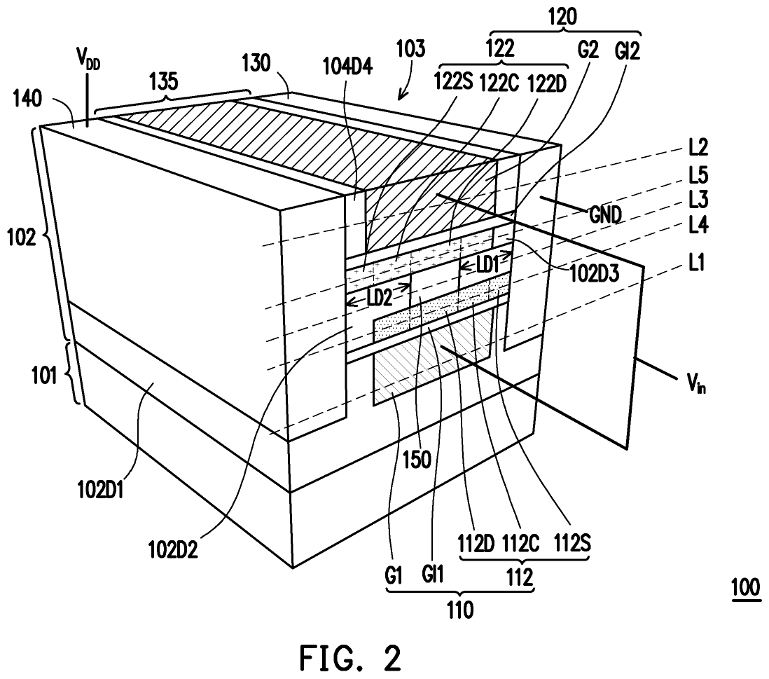

FIG. 2 is a perspective view schematically illustrating a semiconductor die in accordance with some embodiments of the present disclosure.

Referring to FIG. 1 and FIG. 2, a semiconductor die 100 including a semiconductor device (e.g., an inverter 103) embedded therein is illustrated. The semiconductor die 100 includes a semiconductor substrate 101, an interconnect structure 102 disposed on the semiconductor substrate 101 and the inverter 103 embedded in the interconnect structure 102. In some embodiments, the semiconductor substrate 101 includes metal-oxide-semiconductor field effect transistors (MOSFETs), such as PMOSFET, NMOSFET and CMOSFET or combinations thereof formed thereon; and the embedded inverter 103 is electrically connected to the MOSFETs through the interconnect structure 102. The inverter 103 integrated in the interconnect structure 102 of the semiconductor die 100 may include a first thin film transistor (e.g., the n-type FET illustrated in FIG. 1) 110. a second thin film transistor (e.g., the p-type FET illustrated in FIG. 1) 120, a first contact 130, a second contact 140 laterally spaced apart from the first contact 130, and a third contact 150. The second thin film transistor 120 is stacked over the first thin film transistor 110. wherein the first thin film transistor 110 and the second thin film transistor 120 are disposed in a region 135 between the first contact 130 and the second contact 140. The third contact 150 is disposed in the region 135 between the first contact 130 and the second contact 140, wherein the first thin film transistor 110 and the second thin film transistor 120 are disposed at opposite sides of the third contact 150. Furthermore, the first thin film transistor 110 and the second thin film transistor 120 are electrically connected to the MOSFETs formed on the semiconductor substrate 101 through the interconnect structure 102. In some embodiments, the first thin film transistor 110 and the second thin film transistor 120 are spaced apart from the semiconductor substrate 101 by at least on dielectric layer 102D1 of the interconnect structure 102.

The first thin film transistor 110 may include a first gate G1 and a first semiconductor layer 112. The second thin film transistor 120 may include a second gate G2 and a second semiconductor layer 122. The second gate G2 is disposed over the first gate G1, and the third contact 150 is disposed between the first gate G1 and the second gate G2. The first semiconductor layer 112 is disposed between the first gate G1 and the third contact 150. The first semiconductor layer 112 is laterally spaced apart from the second contact 140, and the second semiconductor layer 122 is laterally spaced apart from the first contact 130. The first semiconductor layer 112 of the first thin film transistor 110 laterally extends from a bottom surface of the third contact 150 to a first sidewall of the first contact 130, and the second semiconductor layer 122 of the second thin film transistor 120 laterally extends from a top surface of the third contact 150 to a second sidewall of the second contact 140. As illustrated in FIG. 2, a portion of the top surface of the first semiconductor layer 112 is in contact with the bottom surface of the third contact 150, and a sidewall (e.g., the sidewall on the right-hand side) of the first semiconductor layer 112 is in contact with the first sidewall of the first contact 130. Furthermore, a portion of the bottom surface of the second semiconductor layer 212 is in contact with the top surface of the third contact 150, and a sidewall (e.g., the sidewall on the left-hand side) of the second semiconductor layer 212 is in contact with the second sidewall of the second contact 140.

The first semiconductor layer 112 may be an n-type doped semiconductor layer, and the second semiconductor layer 122 may be a p-type doped semiconductor layer. The first semiconductor layer 112 includes a first channel region 112C, a first source region 112S laterally in contact with the first contact 130, and a first drain region 112D in contact with the third contact 150. The first channel region 112C laterally extends from the first drain region 112D to the first contact 130. The first channel region 112C and the first drain region 112D are overlapped with the underlying first gate G1, and the first drain region 112D is vertically sandwiched between the first gate G1 and the third contact 150. The second semiconductor layer 122 is disposed between the second gate G2 and the third contact 150. The second semiconductor layer 122 includes a second channel region 122C laterally in contact with the second contact 140 and a second drain region 122D in contact with the third contact 150, and the second channel region 122C laterally extends from the second drain region 122D to the second contact 140. Furthermore, the second channel region 122C and the second drain region 122D are overlapped with the overlying second gate G2, and the second drain region 122D is vertically sandwiched between the second gate G2 and the third contact 150.

As illustrated in FIG. 2, the first gate G1 and the second gate G2 are disposed between first contact 130 and the second contact 140. In some embodiments, the first gate G1 is located at a first level height L1, the second gate G2 is located at a second level height L2 which is different from the first level height L1, the third contact 150 is located a third level height L3 between the first level height L1 and the second level height L2. The first contact 130 may extend vertically from the first level height L1 to the second level height L2. The first semiconductor layer 112 is located at a fourth level height L4 between the first level height L1 and the third level height L3, and the second semiconductor layer 122 is located at a fifth level height L5 between the second level height L2 and the third level height L3. In some embodiments, the first semiconductor layer 112 is laterally spaced apart from the second contact 140, and the second semiconductor layer 122 is laterally spaced apart from the first contact 130. Specifically, the first semiconductor layer 112 is laterally spaced apart from the second contact 140 by a dielectric layer 102D2 of the interconnect structure 102, and the second semiconductor layer 122 is laterally spaced apart from the first contact 130 by another dielectric layer 102D3 of the interconnect structure 102.

The inverter 103 may further include a first gate insulating layer GI1 and a second gate insulating layer GI2, wherein the first gate insulating layer GI1 is disposed between the first gate G1 and the first semiconductor layer 112, and the second gate insulating layer GI2 is disposed between the second gate G2 and the second semiconductor layer 122. The first gate insulating layer GI1 laterally extends between the first contact 130 and the second contact 130. The second gate insulating layer GI2 is disposed above the first gate insulating layer GI1 and laterally extends between the first contact 130 and the second contact 140. The first gate G1 is disposed under the first gate insulating layer GI1. The second gate G2 is disposed over the second gate insulating layer GI2. The first semiconductor layer 112, the second semiconductor layer 122 and the third contact 150 are disposed between the first gate insulating layer GI1 and the second gate insulating layer GI2. The first semiconductor layer 112 laterally extends from the third contact 150 to the first contact 130, and the second semiconductor layer 122 laterally extends from the third contact 150 to the second contact 140.

The third contact 150, the first gate G1, the first semiconductor layer 112, the first gate insulating layer GI1, the second gate G2, the second semiconductor layer 212 and the second gate insulating layer GI2 are respectively located at different level heights. As illustrated in FIG. 2, ends (or sidewalls) of the first gate insulating layer GI1 are in contact with the first contact 130 and the second contact 140, and ends (or sidewalls) of the second gate insulating layer GI2 are in contact with the first contact 130 and the second contact 140. In other words, the first gate insulating layer GI1 and the second gate insulating layer GI2 each extends laterally and continuously between the first contact 130 and the second contact 140. Specifically, ends (or sidewalls) of the first gate insulating layer GI1 and ends (or sidewalls) of the second gate insulating layer GI2 are in contact with sidewalls of the first contact 130 and sidewalls of the second contact 140.

In some embodiments, the first semiconductor layer 112, the second semiconductor layer 122 and the third contact 150 are disposed between the first gate insulating layer GI1 and the second gate insulating layer GI2. The first contact 130 is laterally spaced apart from the third contact 150 by a first lateral distance LD1, the second contact 140 is laterally spaced apart from the third contact 150 by a second lateral distance LD2, and the first lateral distance LD1 may be different from the second lateral distance LD2. For example, the first lateral distance LD1 between the first contact 130 and the third contact 150 is greater than 150 nanometers, and the second lateral distance LD2 between the second contact 140 and the third contact 150 is greater than 150 nanometers.

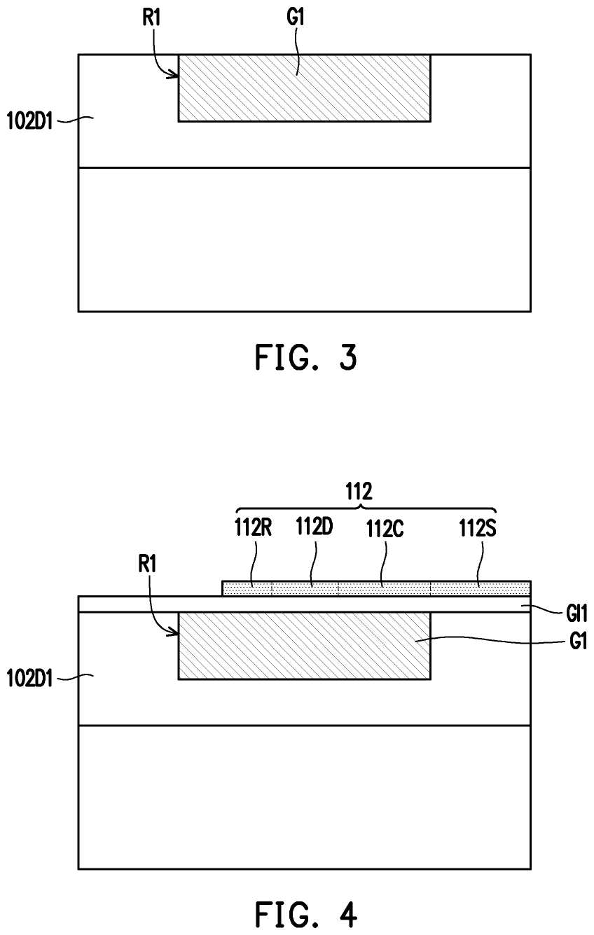

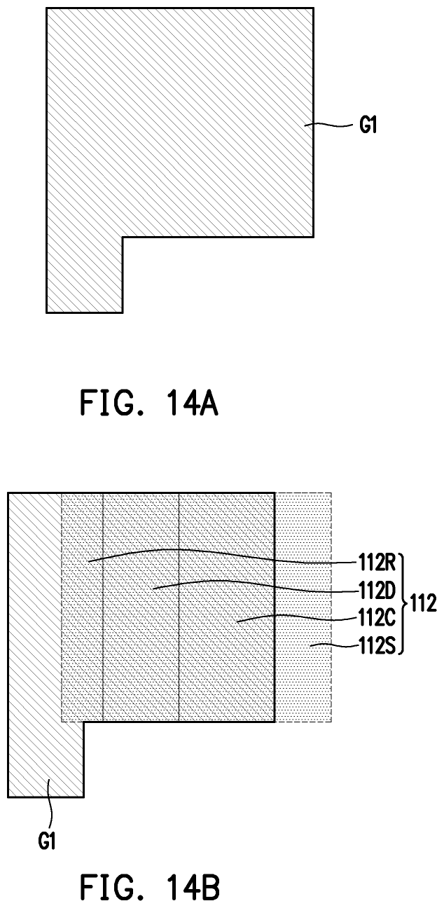

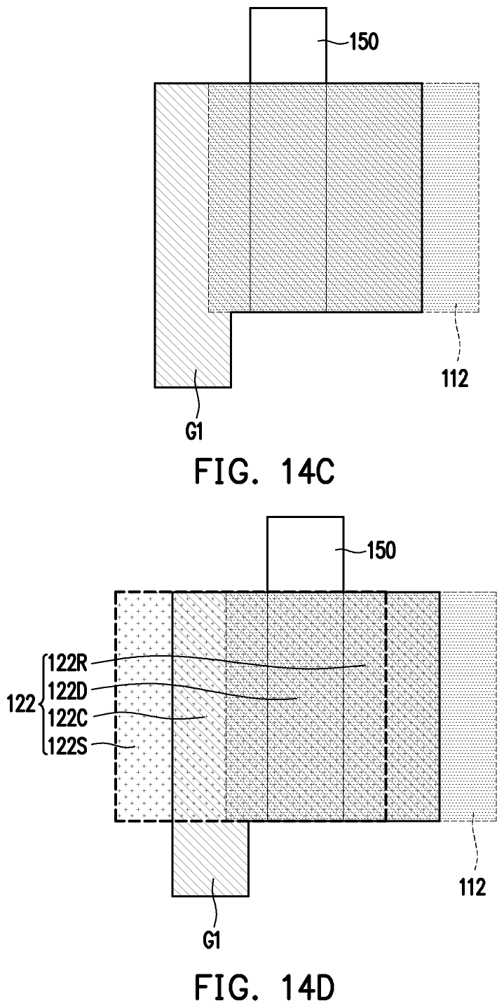

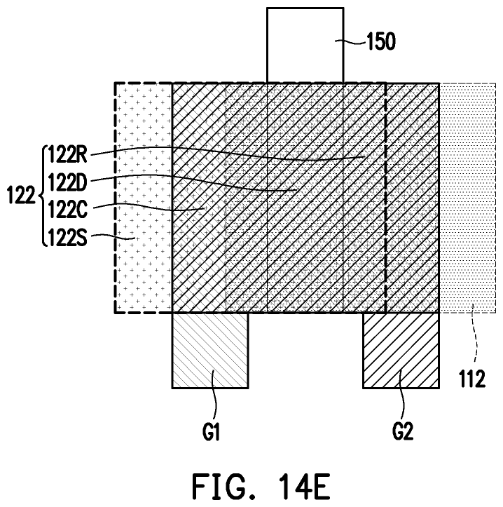

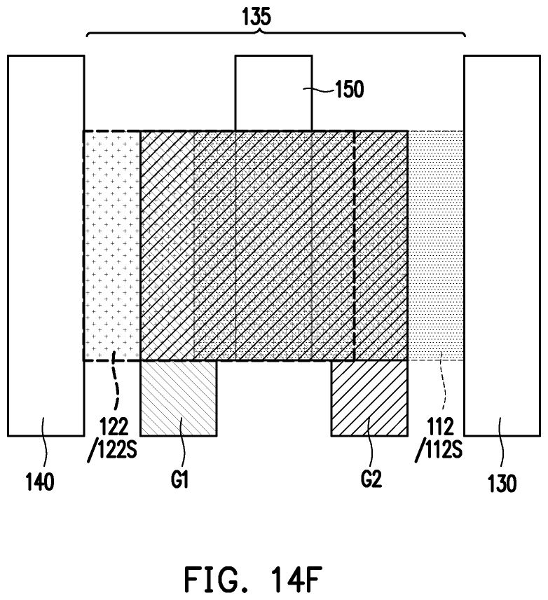

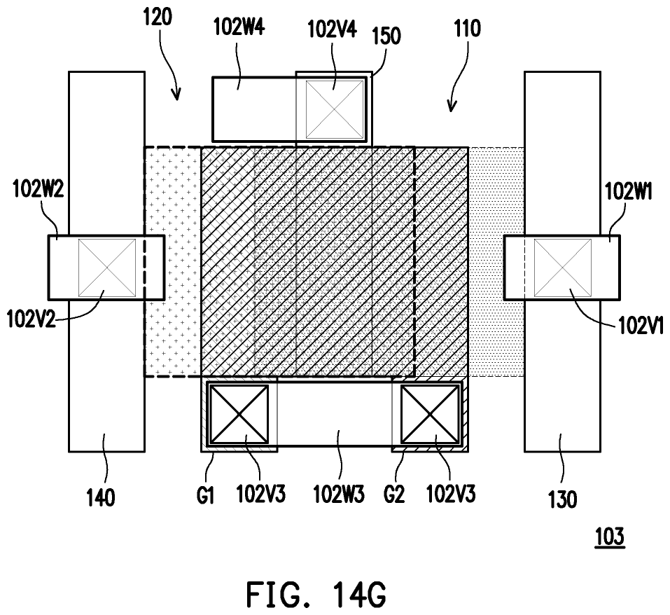

FIG. 3 through FIG. 13 are cross-sectional views schematically illustrating a process flow for fabricating an inverter embedded in an interconnect structure of a semiconductor die in accordance with some embodiments of the present disclosure. FIG. 14A through FIG. 14G schematically illustrate layouts of various thin films in an inverter in accordance with some embodiments of the present disclosure.

Referring to FIG. 3 and FIG. 14A, a semiconductor substrate 101 having at least one dielectric layer 102D1 formed thereon is provided. The semiconductor substrate 101 may include an elementary semiconductor (e.g., silicon or germanium in a crystalline, a polycrystalline, or an amorphous structure, etc.), a compound semiconductor (e.g., SiC. GaAs, GaP, InP, InAs, and/or InSb, etc.), an alloy semiconductor (e.g., SiGe, GaAsP, AlInAs, AlGaAs, GaInAs, GaInP, etc.), combinations thereof, or other suitable materials. In some embodiments, the semiconductor substrate 101 is a semiconductor substrate having a multilayer structure or any suitable substrate. In some embodiments, semiconductor devices are formed in the semiconductor substrate 101, and may include active devices (e.g., transistors, diodes, etc.) and/or passive devices (e.g., capacitors, resistors, inductors, etc.), or other suitable electrical devices. The at least one dielectric layer 102D1 may be a part of the above-mentioned interconnect structure 102 (illustrated in FIG. 2). In some embodiments, the interconnect structure 102 (illustrated in FIG. 2) includes stacked dielectric layers and interconnect wirings embedded in the stacked dielectric layers, and the dielectric layer 102D1 is one of the stacked dielectric layers. The material of the dielectric layer 102D1 may be or include silicon dioxide, silicon nitride, silicon oxynitride or other inorganic dielectric material.

A patterning process is performed to form a recess R in the dielectric layer 102D1. In some embodiments, the patterning process performed on the dielectric layer 102D1 includes a photolithography process followed by an etch process. The depth of the recess R formed in the dielectric layer 102D1 may be less than or substantially equal to the thickness of the dielectric layer 102D1. After forming the recess R in the dielectric layer 102D1, a conductive material is formed on the dielectric layer 102D1 to fill the recess R as well as cover the top surface of the dielectric layer 102D1. The material of the conductive material may be or include copper or other metallic material. The conductive material may be formed on the dielectric layer 102D1 by a chemical vapor deposition (CVD) process, a physical vapor deposition (PVD) process or other suitable deposition process. After depositing the conductive material on the top surface of the dielectric layer 102D1, a removal process is performed to remove portions of the conductive material until the top surface of the dielectric layer 102D1 is revealed such that a first gate G1 is formed in the recess R of the dielectric layer 102D1. The removal process for removing the excess portion of the conductive material may be or include a chemical mechanical polishing (CMP) process, a mechanical grinding process, an etch process, combinations thereof or other suitable removal process.

As illustrated in FIG. 3, the top surface of the first gate G1 substantially levels with the top surface of the dielectric layer 102D1. In some other embodiments, the top surface of the first gate G1 is slightly lower than the top surface of the dielectric layer 102D1 due to the polishing selectivity of the CMP process, the grinding selectivity of the mechanical grinding process or the etch selectivity of the etch process. In some alternative embodiments, the top surface of the first gate G1 is slightly higher than the top surface of the dielectric layer 102D1 due to the polishing selectivity of the CMP process, the grinding selectivity of the mechanical grinding process or the etch selectivity of the etch process.

Referring to FIG. 4 and FIG. 14B, a first gate insulating layer GI1 is deposited to cover the top surface of the first gate G1 and the top surface of the dielectric layer 102D1. The material of the first gate insulating layer GI1 may be or include silicon dioxide, silicon nitride, silicon oxynitride or other insulating material. The first gate insulating layer GI1 may be formed by a chemical vapor deposition (CVD) process, a physical vapor deposition (PVD) process or other suitable deposition process.

After forming the first gate insulating layer GI1, a first semiconductor layer 112 is formed on the first gate insulating layer GI1. The material of the first semiconductor layer 112 may be or include n-type doped indium gallium zinc oxide (IGZO), indium tin zinc oxide (ITZO), indium zinc oxide (IZO) or other suitable semiconductor oxide material. The first semiconductor layer 112 may be formed by a chemical vapor deposition (CVD) process, a physical vapor deposition (PVD) process or other suitable deposition process. As illustrated in FIG. 4 and FIG. 14B, the first semiconductor layer 112 includes a first channel region 112C, a first source region 112S and a first drain region 112D, wherein the first channel region 112C laterally extends from the first drain region 112D to the first source region 112S. The first channel region 112C and the first drain region 112D are vertically overlapped with the underlying first gate G1, and the first source region 112S is not vertically overlapped with the underlying first gate G1. Furthermore, the first channel region 112C, the first source region 112S and the first drain region 112D are spaced apart from the first gate G1 by the first gate insulating layer GI1.

As illustrated in FIG. 4 and FIG. 14B, the first semiconductor layer 112 may further include a first offset region 112R in contact with the first drain region 112D, wherein the first offset region 112R is vertically overlapped with the underlying first gate G1, and the first drain region 112D laterally extends from the first offset region 112R to the first channel region 112C. In other words, the first drain region 112D and the first offset region 112R are located at a first side (e.g., the left-hand side) of the first channel region 112C, the first source region 112S is located at a second side (e.g., the right-hand side) of the first channel region 112C, and the first side is opposite to the second side.

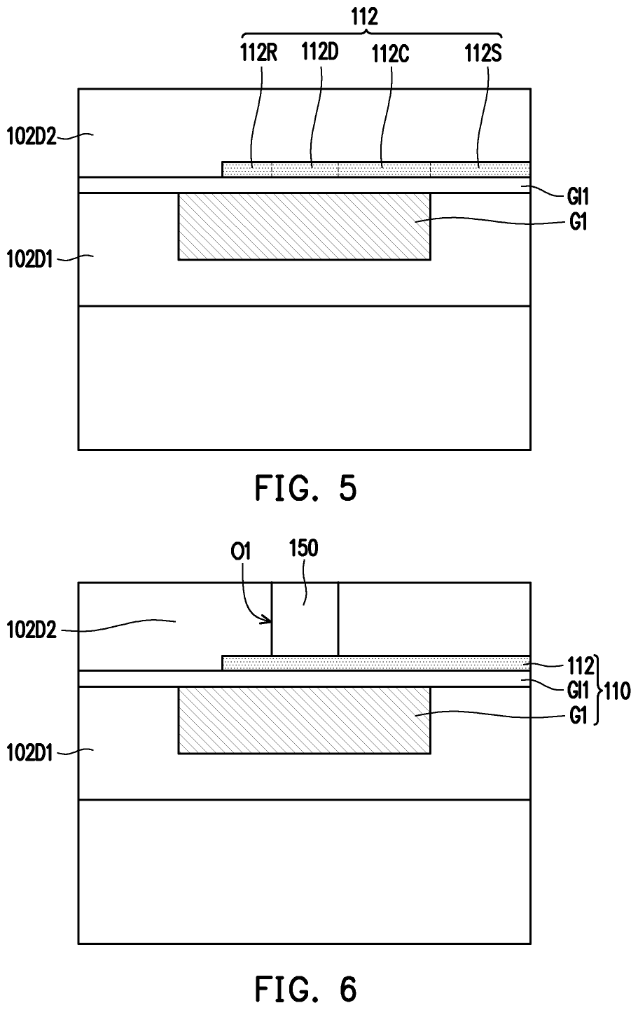

Referring to FIG. 5, a dielectric layer 102D2 is formed to cover the first semiconductor layer 112 and a portion of the first gate insulating layer GI1 uncovered by the first semiconductor layer 112. The dielectric layer 102D2 is one of the stacked dielectric layers of the interconnect structure 102 (illustrated in FIG. 2). The material of the dielectric layer 102D2 may be or include silicon dioxide, silicon nitride, silicon oxynitride or other inorganic dielectric material. As illustrated in FIG. 5, the dielectric layer 102D2 is spaced apart from the dielectric layer 102D1 by the first gate insulating layer GI1.

Referring to FIG. 6 and FIG. 14C, a patterning process is performed to form a through opening O1 in the dielectric layer 102D2. In some embodiments, the patterning process performed on the dielectric layer 102D2 includes a photolithography process followed by an etch process. The through opening O1 penetrates through the dielectric layer 102D2 and the first drain region 112D of the first semiconductor layer 112 is revealed by the through opening O1. After forming the through opening 01 in the dielectric layer 102D2, a conductive material is formed on the dielectric layer 102D2 to fill the through opening O1 as well as cover the top surface of the dielectric layer 102D2. The material of the conductive material may be or include copper or other metallic material. The conductive material may be formed on the dielectric layer 102D2 by a chemical vapor deposition (CVD) process, a physical vapor deposition (PVD) process or other suitable deposition process. After depositing the conductive material on the top surface of the dielectric layer 102D2, a removal process is performed to remove portions of the conductive material until the top surface of the dielectric layer 102D2 is revealed such that a third contact 150 is formed in the through opening O1 of the dielectric layer 102D2. The removal process for removing the excess portion of the conductive material may be or include a chemical mechanical polishing (CMP) process, a mechanical grinding process, an etch process, combinations thereof or other suitable removal process. An ohmic contact interface is formed between the bottom surface of the third contact 150 and the top surface of the first drain region 112D.

As illustrated in FIG. 6, the top surface of the third contact 150 substantially levels with the top surface of the dielectric layer 102D2. In some other embodiments, the top surface of the third contact 150 is slightly lower than the top surface of the dielectric layer 102D2 due to the polishing selectivity of the CMP process, the grinding selectivity of the mechanical grinding process or the etch selectivity of the etch process. In some alternative embodiments, the top surface of the third contact 150 is slightly higher than the top surface of the dielectric layer 102D2 due to the polishing selectivity of the CMP process, the grinding selectivity of the mechanical grinding process or the etch selectivity of the etch process.

Furthermore, the boundary between the first drain region 112D and the first offset region 112R is substantially aligned with one sidewall (e.g., the left-hand sidewall) of the third contact 150, and the boundary between the first drain region 112D and the first channel region 112C is substantially aligned with another sidewall (e.g., the right-hand sidewall) of the third contact 150. In other words, the boundaries of the first drain region 112D of the first semiconductor layer 112 is defined by sidewalls of the third contact 150. As illustrated in FIG. 6, the third contact 150 is vertically overlapped with the first drain region 112D. Furthermore, the first offset region 112R, the first channel region 112C and the first source region 112S are not vertically overlapped with the third contact 150.

Only the first drain region 112D is vertically overlapped with the third contact 150 and the underlying first gate G1. In other words, the first drain region 112D is vertically sandwiched between the third contact 150 and the underlying first gate G1. In addition, only the first source region 112S is not vertically overlapped with the third contact 150 and the underlying first gate G1.

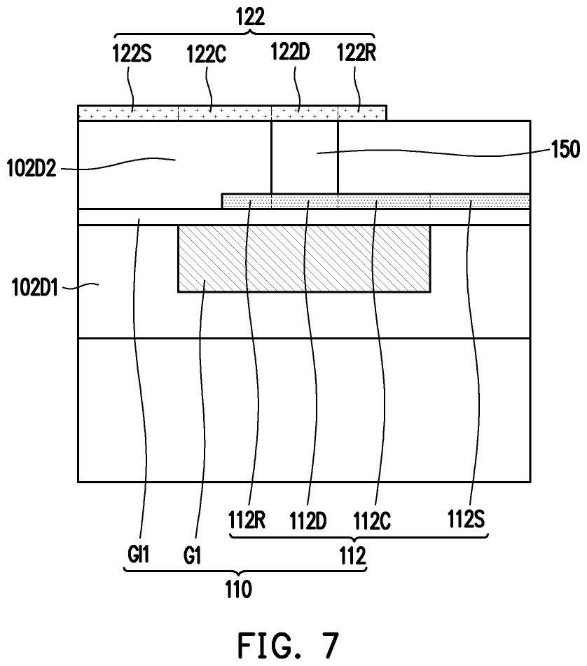

Referring to FIG. 7 and FIG. 14D, a second semiconductor layer 122 is formed to cover the dielectric layer 102D2 and the third contact 150. The material of the second semiconductor layer 122 may be or include p-type doped indium gallium zinc oxide (IGZO), indium tin zinc oxide (ITZO), indium zinc oxide (IZO) or other suitable semiconductor oxide material. The second semiconductor layer 122 may be formed by a chemical vapor deposition (CVD) process, a physical vapor deposition (PVD) process or other suitable deposition process. As illustrated in FIG. 7 and FIG. 14D, the second semiconductor layer 122 includes a second channel region 122C, a second source region 122S and a second drain region 122D, wherein the second channel region 122C laterally extends from the second drain region 122D to the second source region 122S. An ohmic contact interface is formed between the top surface of the third contact 150 and the bottom surface of the second drain region 122D of the second semiconductor layer 122.

The second semiconductor layer 122 may further include a second offset region 122R in contact with the second drain region 122D, wherein the second drain region 122D laterally extends from the second offset region 122R to the second channel region 122C. In other words, the second drain region 122D and the second offset region 122R are located at a first side (e.g., the right-hand side) of the second channel region 122C, the second source region 122S is located at a second side (e.g., the left-hand side) of the second channel region 122C, and the first side is opposite to the second side.

The boundary between the second drain region 122D and the second offset region 112R is substantially aligned with one sidewall (e.g., the right-hand sidewall) of the third contact 150, and the boundary between the second drain region 122D and the second channel region 122C is substantially aligned with another sidewall (e.g., the left-hand sidewall) of the third contact 150. In other words, the boundaries of the second drain region 122D of the second semiconductor layer 122 is defined by sidewalls of the third contact 150. As illustrated in FIG. 7, the third contact 150 is vertically overlapped with the first drain region 112D and the second drain region 122D. Furthermore, the second offset region 122R, the second channel region 122C and the second source region 122S are not vertically overlapped with the third contact 150.

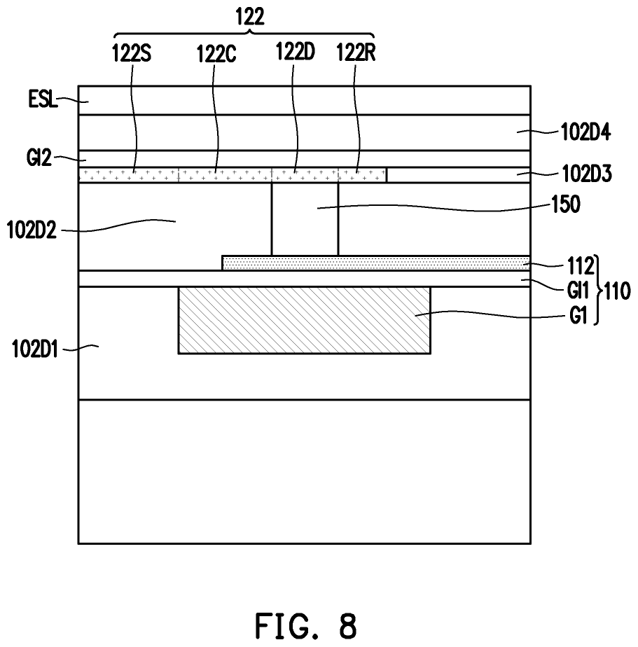

Referring to FIG. 8, after forming the second semiconductor layer 122, a dielectric pattern 102D3 is formed on a revealed portion of the dielectric layer 102D2. The dielectric pattern 102D3 is one of the stacked dielectric layers of the interconnect structure 102 (illustrated in FIG. 2). The material of the dielectric pattern 102D3 may be or include silicon dioxide, silicon nitride, silicon oxynitride or other inorganic dielectric material. The revealed portion of the dielectric layer 102D2 is not covered by the second semiconductor layer 122, and the revealed portion of the dielectric layer 102D2 is in contact with the dielectric pattern 102D3. The top surface of the dielectric layer 102D2 substantially levels with the top surface of the dielectric pattern 102D3 which may facilitate the subsequently performed processes. In other words, the dielectric pattern 102D3 may serve as a planarization layer and the step coverage of the subsequently formed thin films may be enhanced. In some other embodiments, the formation of the dielectric pattern 102D3 is omitted.

After forming the second semiconductor layer 122, a second gate insulating layer GI2 is deposited to cover the top surface of the second semiconductor layer 122 and the top surface of the dielectric pattern 102D3. The material of the second gate insulating layer GI2 may be or include silicon dioxide, silicon nitride, silicon oxynitride or other insulating material. The second gate insulating layer GI2 may be formed by a chemical vapor deposition (CVD) process, a physical vapor deposition (PVD) process or other suitable deposition process.

A dielectric layer 102D4 and an etch stop layer ESL are sequentially formed over the second gate insulating layer GI2. The dielectric layer 102D4 is one of the stacked dielectric layers of the interconnect structure 102 (illustrated in FIG. 2). The material of the dielectric layer 102D4 may be or include silicon dioxide, silicon nitride, silicon oxynitride or other inorganic dielectric material. As illustrated in FIG. 8, the dielectric layer 102D4 is spaced apart from the dielectric pattern 102D3 and the second semiconductor layer 122 by the second gate insulating layer GI2. Furthermore, the etch stop layer ESL is also one of the stacked dielectric layers of the interconnect structure 102 (illustrated in FIG. 2). The material of the etch stop layer ESL may be or include silicon nitride or other etch stop material. As illustrated in FIG. 8, the etch stop layer ESL is spaced apart from the dielectric pattern 102D3 and the second semiconductor layer 122 by the second gate insulating layer GI2 and the dielectric layer 102D4. In some other embodiments, the formation of the etch stop layer ESL is omitted.

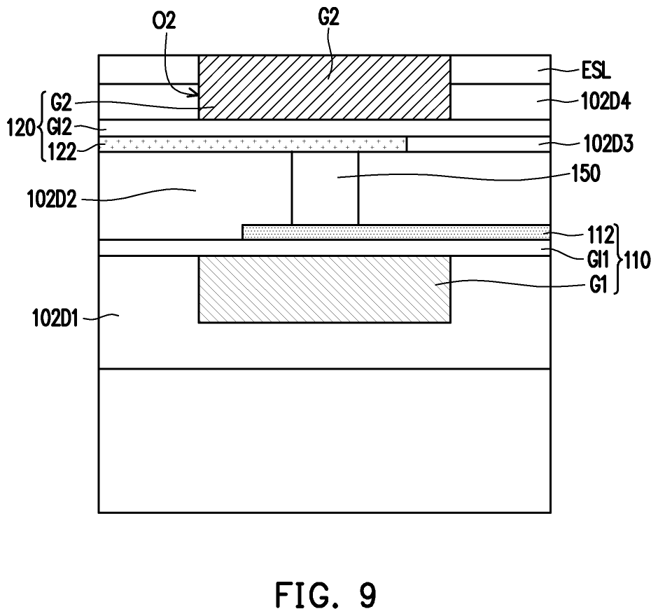

Referring to FIG. 9 and FIG. 14E, a patterning process is performed to form a through opening O2 in the dielectric layer 102D4 and the etch stop layer ESL. In some embodiments, the patterning process performed on the dielectric layer 102D4 and the etch stop layer ESL includes a photolithography process followed by an etch process. The depth of the through opening 02 formed in the dielectric layer 102D4 and the etch stop layer ESL may be substantially equal to the sum of the thickness of the dielectric layer 102D4 and the etch stop layer ESL. After forming the through opening O2 in the dielectric layer 102D4 and the etch stop layer ESL, a conductive material is formed on the etch stop layer ESL to fill the through opening O2 as well as cover the top surface of the etch stop layer ESL. The material of the conductive material may be or include copper or other metallic material. The conductive material may be formed on the etch stop layer ESL by a chemical vapor deposition (CVD) process, a physical vapor deposition (PVD) process or other suitable deposition process. After depositing the conductive material on the top surface of the etch stop layer ESL, a removal process is performed to remove portions of the conductive material until the top surface of the etch stop layer ESL is revealed such that a second gate G2 is formed in the through opening O2 of the dielectric layer 102D4 and the etch stop layer ESL. The removal process for removing the excess portion of the conductive material may be or include a chemical mechanical polishing (CMP) process, a mechanical grinding process, an etch process, combinations thereof or other suitable removal process.

As illustrated in FIG. 9, the top surface of the second gate G2 substantially levels with the top surface of the etch stop layer ESL. In some other embodiments, the top surface of the second gate G2 is slightly lower than the top surface of the etch stop layer ESL due to the polishing selectivity of the CMP process, the grinding selectivity of the mechanical grinding process or the etch selectivity of the etch process. In some alternative embodiments, the top surface of the second gate G2 is slightly higher than the top surface of the etch stop layer ESL due to the polishing selectivity of the CMP process, the grinding selectivity of the mechanical grinding process or the etch selectivity of the etch process.

The second channel region 122C and the second drain region 122D are vertically overlapped with the overlying second gate G2, and the second source region 122S is not vertically overlapped with the overlying second gate G2. Furthermore, the second channel region 122C, the second source region 122S and the second drain region 122D are spaced apart from the overlying second gate G2 by the second gate insulating layer GI2.

After forming the second gate G2, a first FET (e.g., an n-type FET) 110 and a second FET (e.g., a p-type FET) 120 stacked over and electrically connected to the second FET 110 are fabricated. The first FET 110 includes the first gate G1, the first gate insulating layer GI1 and the first semiconductor layer 112. The second FET 120 includes the second gate G2, the second gate insulating layer G12 and the second semiconductor layer 122. The third contact 150 is vertically sandwiched between the first FET 110 and the second FET 120. Both the first semiconductor layer 112 and the second semiconductor layer 122 are in contact with the third contact 150. A first ohmic contact interface is formed between the top surface of the first semiconductor layer 112 and the bottom surface of the third contact 150, and a second ohmic contact interface is formed between the bottom surface of the second semiconductor layer 122 and the top surface of the third contact 150.

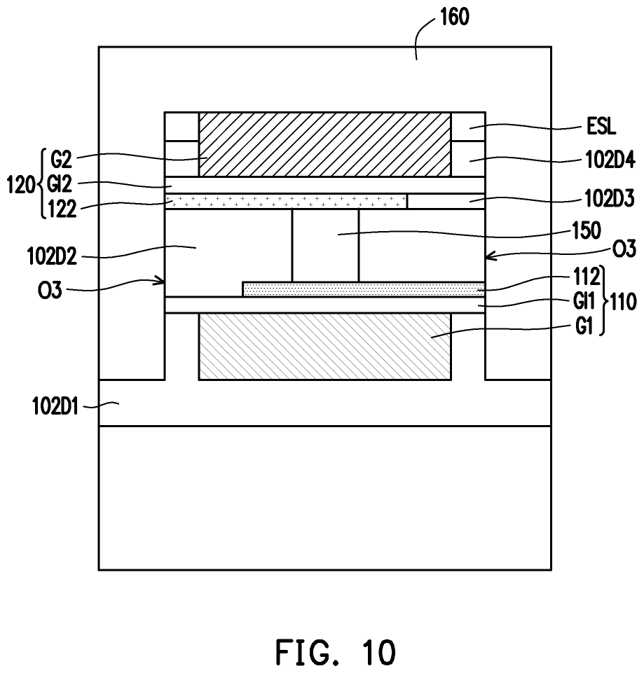

Referring to FIG. 10, a patterning process is performed to form through openings O3 and O4. The through opening O3 penetrates through the etch stop layer ESL, the dielectric layer 102D4, the second gate insulating layer GI2, the dielectric pattern 102D3, the dielectric layer 102D2, the first semiconductor layer 112, and the first gate insulating layer GI1. The through opening O3 further extends downwardly into the dielectric layer 102D1. The bottom of the through opening O3 may substantially level with the bottom surface of the first gate G1. The through opening O4 penetrates through the etch stop layer ESL, the dielectric layer 102D4, the second gate insulating layer GI2, the second semiconductor layer 122, the dielectric pattern 102D3, the dielectric layer 102D2, and the first gate insulating layer GI1. The through opening O4 further extends downwardly into the dielectric layer 102D1. The bottom of the through opening 04 may substantially level with the bottom surface of the first gate G1. In some embodiments, the patterning process for simultaneously forming the through openings O3 and O4 includes a photolithography process followed by an etch process.

After forming the through openings O3 and O4, a conductive material 160 is formed on the etch stop layer ESL and the second gate G2 to fill the through openings O3 and O4. The material of the conductive material 160 may be or include copper or other metallic material. The conductive material 160 may be formed on the etch stop layer ESL and the second gate G2 by a chemical vapor deposition (CVD) process, a physical vapor deposition (PVD) process or other suitable deposition process.

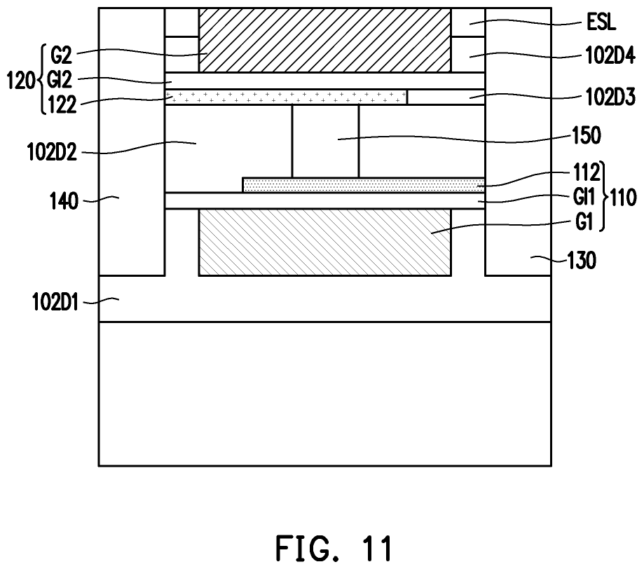

Referring to FIG. 10, FIG. 11 and FIG. 14F, after depositing the conductive material 160 on the top surfaces of the etch stop layer ESL and the second gate G2, a removal process is performed to remove portions of the conductive material 160 until the top surface of the etch stop layer ESL and the second gate G2 are revealed such that a first contact 130 and a second contact 140 are respectively formed in the through openings O3 and O4. The removal process for removing the excess portion of the conductive material 160 may be or include a chemical mechanical polishing (CMP) process, a mechanical grinding process, an etch process, combinations thereof or other suitable removal process.

The first contact 130 and the second contact 140 define the region 135, and the first gate G1, the first gate insulating layer GI1, the first semiconductor layer 112, the third contact 150, the second semiconductor layer 122, the second gate insulating layer GI2 and the second gate G2 are distributed in the region 135 between the first contact 130 and the second contact 140. The top surfaces of the first contact 130 and the second contact 140 substantially level with the top surface of the etch stop layer ESL. In some other embodiments, the top surfaces of the first contact 130 and the second contact 140 are slightly lower than the top surface of the etch stop layer ESL due to the polishing selectivity of the CMP process, the grinding selectivity of the mechanical grinding process or the etch selectivity of the etch process. In some alternative embodiments, the top surfaces of the first contact 130 and the second contact 140 are slightly higher than the top surface of the etch stop layer ESL due to the polishing selectivity of the CMP process, the grinding selectivity of the mechanical grinding process or the etch selectivity of the etch process.

As illustrated in FIG. 11, the first gate G1 is laterally spaced apart from the first contact 130 and the second contact 140 by different portions of the dielectric layer 102D1. The first gate G1 is electrically insulated from the first contact 130 and the second contact 140. Two opposite ends (or sidewalls) of the first gate insulating layer GI1 are respectively in contact with the first contact 130 and the second contact 140. In other words, the first gate insulating layer GI1 extends laterally and continuously between the first contact 130 and the second contact 140. Furthermore, an end (i.e., the first source region 112S) of the first semiconductor layer 112 is in contact with and electrically connected to the first contact 130. The first semiconductor layer 112 is laterally spaced apart from the second contact 140 by the dielectric layer 102D2. The first semiconductor layer 112 is electrically insulated from the second contact 140.

The third contact 150 is laterally spaced apart from the first contact 130 and the second contact 140 by the dielectric layer 102D2. The third contact 150 is electrically insulated from the first contact 130 and the second contact 140.

The second semiconductor layer 122 is laterally spaced apart from the first contact 130 by the dielectric pattern 103D3 by the dielectric pattern 103D3. The second semiconductor layer 122 is electrically insulated from the first contact 130. Furthermore, an end (i.e., the second source region 122S) of the second semiconductor layer 122 is in contact with and electrically connected to the second contact 140. Two opposite ends (or sidewalls) of the second gate insulating layer GI2 are respectively in contact with the sidewall of the first contact 130 and the sidewall of the second contact 140. In other words, the second gate insulating layer GI2 extends laterally and continuously between the first contact 130 and the second contact 140. The second gate G2 is laterally spaced apart from the first contact 130 and the second contact 140 by different portions of the dielectric layer 102D4 and different portions of the etch stop layer ESL. The second gate G2 is electrically insulated from the first contact 130 and the second contact 140.

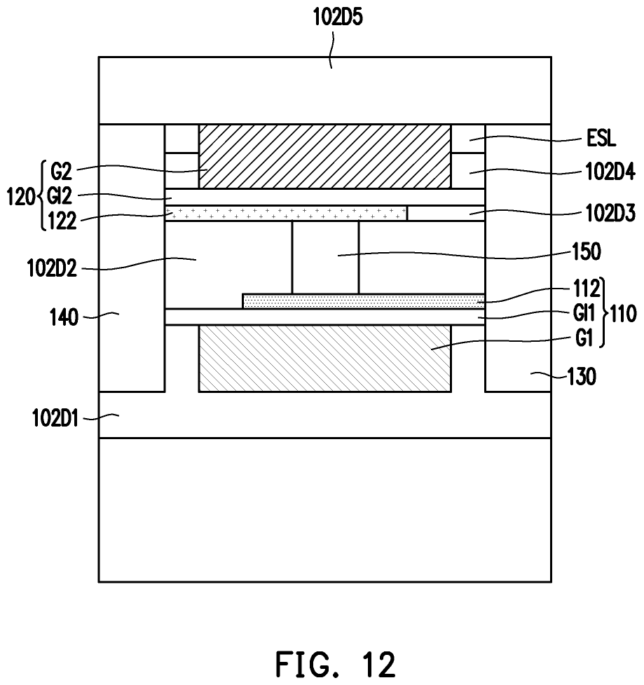

Referring to FIG. 12, a dielectric layer 102D5 is formed to cover the second gate G2, the etch stop layer ESL, the first contact 130 and the second contact 140. The dielectric layer 102D5 may be a part of the above-mentioned interconnect structure 102 (illustrated in FIG. 2). In some embodiments, the interconnect structure 102 (illustrated in FIG. 2) includes stacked dielectric layers and interconnect wirings embedded in the stacked dielectric layers, and the dielectric layer 102D5 is one of the stacked dielectric layers. The material of the dielectric layer 102D5 may be or include silicon dioxide, silicon nitride, silicon oxynitride or other inorganic dielectric material.

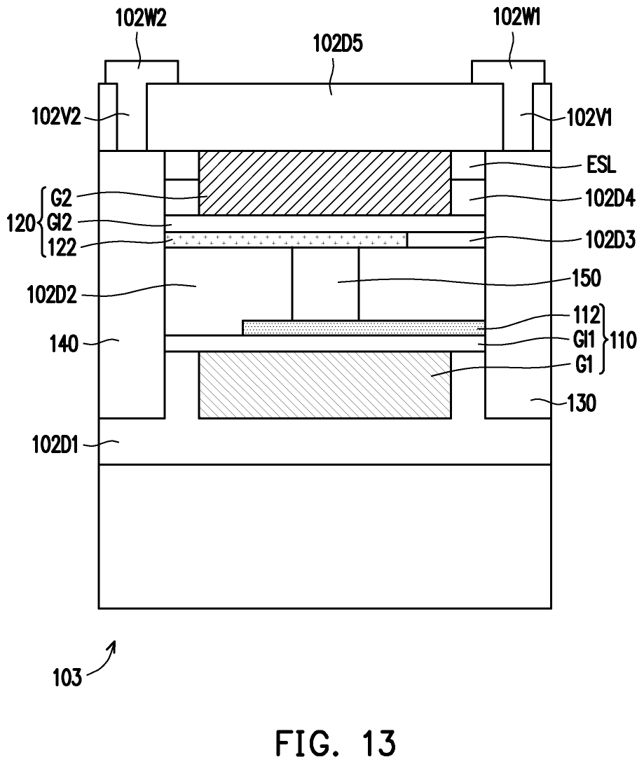

Referring to FIG. 13 and FIG. 14G, contact vias 102V1, 102V2 and 102V3 which penetrate though the dielectric layer 102D5 are formed. The contact via 102V1 lands on and is electrically connected to the first contact 130, the contact via 102V2 lands on and is electrically connected to the second contact 140, and the contact vias 102V3 land on and are electrically connected to the first gate G1 and the second gate G2. Furthermore, a contact via 102V4 which penetrates through the dielectric layer 102D5, the etch stop layer ESL, the dielectric layer 102D4 and the second gate insulating layer GI2 is formed over the third contact 150. The contact via 102V4 lands on and is electrically connected to the third contact 150. The height of the contact via 102V4 may be greater than the height of the contact vias 102V1, 102V2 and 102V3. In some embodiments, the contact vias 102V1. 102V2, 102V3 and 102V4 are formed through a photolithography process followed by an etch process.

As illustrated in FIG. 2, FIG. 13 and FIG. 14G, interconnect wirings 102W1, 102W2, 102W3 and 102W4 of the interconnect structure 102 are formed. The interconnect wiring 102W1 is formed on and electrically connected to the contact via 102V1, the interconnect wiring 102W2 is formed on and electrically connected to the contact via 102V2, the interconnect wiring 102W3 is formed on and electrically connected to the contact vias 102V3, and the interconnect wiring 102W4 is formed on and electrically connected to the contact via 102V4. Through the interconnect wiring 102W1, the first contact 130 is electrically connected the low voltage level GND (e.g., electrically grounded). Through the interconnect wiring 102W2, the second contact 140 is electrically connected the high voltage level V_{DD} (e.g., a supply voltage VDD). Through the interconnect wiring 102W3, both the first gate G1 and the second gate G2 are electrically connected to each other, and the input voltage Vin can be applied to the first gate G1 and the second gate G2. Furthermore, through the interconnect wiring 102W4 formed on the third contact 150, the third contact 150 can outputs the high output voltage Vₒᵤₜ based on the input voltage Vᵢₙ applied to the first gate G1 and the second gate G2.

In the above-mentioned embodiments, the VTC shifting issue of the inverter 103 may be improved by freely tuning the lateral dimension and the position of the output contact (i.e., the third contact 150), such that the inverter 103 may have symmetry VTC. Furthermore, the fabrication process flow of the inverter 103 is compatible with current process, and the inverter 103 can be integrated into an interconnect structure of a semiconductor die easily.

In accordance with some embodiments of the disclosure, a semiconductor device, including a first gate, a second gate disposed over the first gate, a first contact, a second contact, a third contact disposed between the first gate and the second gate, a first semiconductor layer and a second semiconductor layer is provided. The first semiconductor layer is disposed between the first gate and the third contact. The first semiconductor layer includes a first channel region, a first source region laterally in contact with the first contact and a first drain region in contact with the third contact, and the first channel region laterally extends between the first drain region and the first contact. The second semiconductor layer is disposed between the second gate and the third contact. The second semiconductor layer includes a second channel region, a second source region laterally in contact with the second contact and a second drain region in contact with the third contact, and the second channel region laterally extends between the second drain region and the second contact. In some embodiments, the first gate and the second gate are disposed between first contact and the second contact. In some embodiments, the first gate is located at a first level height, the second gate is located at a second level height different from the first level height, the third contact is located a third level height between the first level height and the second level height. In some embodiments, the first contact extends from the first level height to the second level height. In some embodiments, the first semiconductor layer is located at a fourth level height between the first level height and the third level height, and the second semiconductor layer is located at a fifth level height between the second level height and the third level height. In some embodiments, the first semiconductor layer is spaced apart from the second contact, and the second semiconductor layer is spaced apart from the first contact. In some embodiments, the semiconductor device further includes a first gate insulating layer disposed between the first gate and the first semiconductor layer; and a second gate insulating layer disposed between the second gate and the second semiconductor layer. In some embodiments, ends of the first gate insulating layer are in contact with the first contact and the second contact, and ends of the second gate insulating layer are in contact with the first contact and the second contact. In some embodiments, the first semiconductor layer, the second semiconductor layer and the third contact are disposed between the first gate insulating layer and the second gate insulating layer. In some embodiments, the first contact is spaced apart from the third contact by a first lateral distance, the second contact is spaced apart from the third contact by a second lateral distance, and the first lateral distance is different from the second lateral distance.

In accordance with some other embodiments of the disclosure, a semiconductor die including a semiconductor substrate, an interconnect structure disposed on the semiconductor substrate and an inverter embedded in the interconnect structure is provided. The inverter includes a first contact, a second contact laterally spaced apart from the first contact, a first thin film transistor, a second thin film transistor and a third contact. The second thin film transistor is stacked over the first thin film transistor, wherein the first thin film transistor and the second thin film transistor are disposed in a region between the first contact and the second contact. The third contact is disposed in the region between the first contact and the second contact, wherein the first thin film transistor and the second thin film transistor are disposed at opposite sides of the third contact, a first semiconductor layer of the first thin film transistor laterally extends from a bottom surface of the third contact to a first sidewall of the first contact, and a second semiconductor layer of the second thin film transistor laterally extends from a top surface of the third contact to a second sidewall of the second contact. In some embodiments, the semiconductor substrate includes metal-oxide-semiconductor field effect transistors (MOSFETs), and the first thin film transistor and the second thin film transistor are electrically connected to the MOSFETs through the interconnect structure. In some embodiments, the first thin film transistor and the second thin film transistor are spaced apart from the semiconductor substrate by a dielectric layer of the interconnect structure. In some embodiments, the third contact, a first gate of the first thin film transistor, the first semiconductor layer, a first gate insulating layer of the first thin film transistor, a second gate of the second thin film transistor, the second semiconductor layer and a second gate insulating layer of the second thin film transistor are respectively located at different level heights. In some embodiments, the first semiconductor layer is spaced apart from the second contact, and the second semiconductor layer is spaced apart from the first contact. In some embodiments, the first contact is spaced apart from the third contact by a first lateral distance, the second contact is spaced apart from the third contact by a second lateral distance, and the first lateral distance is different from the second lateral distance.

In accordance with some other embodiments of the disclosure, a semiconductor device including a first contact, a second contact, a first gate insulating layer, a second gate insulating layer, a first gate, a second gate, a first semiconductor layer, a second semiconductor layer and a third contact is provided. The second contact is laterally spaced apart from the first contact. The first gate insulating layer laterally extends between the first contact and the second contact. The second gate insulating layer is disposed above the first gate insulating layer and laterally extends between the first contact and the second contact. The first gate is disposed under the first gate insulating layer. The second gate is disposed over the second gate insulating layer. The first semiconductor layer, the second semiconductor layer and the third contact are disposed between the first gate insulating layer and the second gate insulating layer. The first semiconductor layer laterally extends from the third contact to the first contact, and the second semiconductor layer laterally extends from the third contact to the second contact. In some embodiments, first ends of the first gate insulating layer and second ends of the second gate insulating layer are in contact with first sidewalls of the first contact and second sidewalls of the second contact. In some embodiments, the first semiconductor layer is laterally spaced apart from the second contact, and the second semiconductor layer is laterally spaced apart from the first contact. In some embodiments, the semiconductor die further includes an etch stop layer in contact with the second gate, the first contact and the second contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first gate;
a second gate disposed over the first gate;
a first contact;
a second contact;
a third contact disposed between the first gate and the second gate;
a first semiconductor layer disposed between the first gate and the third contact, wherein the first semiconductor layer comprises a first channel region, a first source region laterally in contact with the first contact and a first drain region in contact with the third contact, and the first channel region laterally extends between the first drain region and the first contact; and
a second semiconductor layer disposed between the second gate and the third contact, wherein the second semiconductor layer comprises a second channel region, a second source region laterally in contact with the second contact and a second drain region in contact with the third contact, and the second channel region laterally extends between the second drain region and the second contact.

2. The semiconductor device as claimed in claim 1, wherein the first gate and the second gate are disposed between first contact and the second contact.

3. The semiconductor device as claimed in claim 1, wherein the first gate is located at a first level height, the second gate is located at a second level height different from the first level height, and the third contact is located a third level height between the first level height and the second level height.

4. The semiconductor device as claimed in claim 3, wherein the first contact extends from the first level height to the second level height.

5. The semiconductor device as claimed in claim 3, wherein the first semiconductor layer is located at a fourth level height between the first level height and the third level height, and the second semiconductor layer is located at a fifth level height between the second level height and the third level height.

6. The semiconductor device as claimed in claim 1, wherein the first semiconductor layer is spaced apart from the second contact, and the second semiconductor layer is spaced apart from the first contact.

7. The semiconductor device as claimed in claim 1 further comprising:
a first gate insulating layer disposed between the first gate and the first semiconductor layer; and
a second gate insulating layer disposed between the second gate and the second semiconductor layer.

8. The semiconductor device as claimed in claim 7, wherein ends of the first gate insulating layer are in contact with the first contact and the second contact, and ends of the second gate insulating layer are in contact with the first contact and the second contact.

9. The semiconductor device as claimed in claim 7, wherein the first semiconductor layer, the second semiconductor layer and the third contact are disposed between the first gate insulating layer and the second gate insulating layer.

10. The semiconductor device as claimed in claim 1, wherein the first contact is spaced apart from the third contact by a first lateral distance, the second contact is spaced apart from the third contact by a second lateral distance, and the first lateral distance is different from the second lateral distance.

11. A semiconductor die, comprising:
a semiconductor substrate;
an interconnect structure disposed on the semiconductor substrate;
an inverter embedded in the interconnect structure, the inverter comprising:
a first contact;
a second contact laterally spaced apart from the first contact;
a first thin film transistor;
a second thin film transistor stacked over the first thin film transistor, wherein the first thin film transistor and the second thin film transistor are disposed in a region between the first contact and the second contact; and
a third contact disposed in the region between the first contact and the second contact, wherein the first thin film transistor and the second thin film transistor are disposed at opposite sides of the third contact, a first semiconductor layer of the first thin film transistor laterally extends from a bottom surface of the third contact to a first sidewall of the first contact, and a second semiconductor layer of the second thin film transistor laterally extends from a top surface of the third contact to a second sidewall of the second contact.

12. The semiconductor die as claimed in claim 11, wherein the semiconductor substrate comprises metal-oxide-semiconductor field effect transistors (MOSFETs), and the first thin film transistor and the second thin film transistor are electrically connected to the MOSFETs through the interconnect structure.

13. The semiconductor die as claimed in claim 11, wherein the first thin film transistor and the second thin film transistor are spaced apart from the semiconductor substrate by a dielectric layer of the interconnect structure.

14. The semiconductor die as claimed in claim 11, wherein the third contact, a first gate of the first thin film transistor, the first semiconductor layer, a first gate insulating layer of the first thin film transistor, a second gate of the second thin film transistor, the second semiconductor layer and a second gate insulating layer of the second thin film transistor are respectively located at different level heights.

15. The semiconductor die as claimed in claim 11, wherein the first semiconductor layer is spaced apart from the second contact, and the second semiconductor layer is spaced apart from the first contact.

16. The semiconductor die as claimed in claim 11, wherein the first contact is spaced apart from the third contact by a first lateral distance, the second contact is spaced apart from the third contact by a second lateral distance, and the first lateral distance is different from the second lateral distance.

17. A method for fabricating a semiconductor device, comprising:
forming a first gate over a semiconductor substrate;
forming a first gate insulating layer on the first gate;
forming a first semiconductor layer on the first gate insulating layer;
forming a first contact on the first semiconductor layer;
forming a second semiconductor layer on the first contact;
forming a second gate insulating layer on the second semiconductor layer;
forming a second gate on the second gate insulating layer; and
after forming the second gate on the second gate insulating layer, forming a second contact and a third contact, wherein the first semiconductor layer, the second semiconductor layer and the first contact are disposed between the first gate insulating layer and the second gate insulating layer, the first semiconductor layer laterally extends from the first contact to the second contact, and the second semiconductor layer laterally extends from the first contact to the third contact.

18. The method as claimed in claim 17 further comprising:
forming a first dielectric layer on the semiconductor substrate, wherein the first gate is formed to embedded in the first dielectric layer.

19. The method as claimed in claim 18 further comprising:
forming a second dielectric layer on the first gate insulating layer and the first semiconductor layer, wherein the first contact is formed to embedded in the second dielectric layer, and the second semiconductor layer is formed on the second dielectric layer; and
forming a third dielectric layer on the second semiconductor layer and the second dielectric layer, wherein the second gate is formed to embedded in the third dielectric layer.

20. The method as claimed in claim 19, wherein the second contact and the third contact are formed to penetrate through the first dielectric layer, the second dielectric layer and the third dielectric layer, the second contact is electrically connected to the first semiconductor layer, and the third contact is electrically connected to the second semiconductor layer.
